(19) United States
(12) Patent Application Publication
(10) Pub. No.: US 2024/0402018 A1
(43) Pub. Date: Dec. 5, 2024

(54) TEMPERATURE DETECTOR AND SEMICONDUCTOR PROCESSING APPARATUS

(71) Applicant: Hitachi High-Tech Corporation, Minato-ku, Tokyo (JP)

(72) Inventors: Yosuke KUROSAKI, Tokyo (JP); Weilin YAN, Tokyo (JP); Kenji MAEDA, Tokyo (JP)

(21) Appl. No.: 18/025,243

(22) PCT Filed: Mar. 16, 2022
(86) PCT No.: PCT/JP2022/011898

§ 371 Date: Aug. 15, 2024

(51) Int. Cl. G01J 5/60

(52) U.S. Cl. CPC G01J 5/60

(57) ABSTRACT

A temperature detector capable of detecting temperature of a semiconductor wafer with high accuracy is provided. In standardizing a spectrum of light measured by a photodetector, a controller uses as a local minimum wavelength a wavelength corresponding to bandgap energy of a semiconductor at absolute zero to set as a local minimum value a minimum value of a light intensity in a wavelength region shorter than the local minimum wavelength, uses as a first maximum wavelength a wavelength corresponding to a difference between bandgap energy and thermal energy of a semiconductor at the highest temperature assumed as a temperature measurement range to set as a local maximum value a value obtained by taking a difference with a local minimum value from the maximum value of the light intensity in a wavelength region shorter than the first maximum wavelength, and performs a difference processing with the local minimum value with respect to the spectrum of the measured light to divide it by the local maximum value, thereby standardizing it.

### TECHNICAL FIELD

The present invention relates to a method and an apparatus of detecting temperature of a semiconductor wafer and, more particularly, method and an apparatus of detecting temperature of the semiconductor wafer while the semiconductor wafer is placed on an upper surface of a sampling stage arranged in a processing chamber inside a vacuum container, or a semiconductor processing apparatus having such a temperature detection mechanism.

### BACKGROUND ART

With spread of mobile devices such as smartphones and development of cloud technology, semiconductor devices are being highly integrated around the world, and highly difficult semiconductor processing technology associated with it is being strongly demanded. The semiconductor processing technology includes a wide range of techniques such as etching technology and exposure technology, but heating technology for performing crystallization and atomic diffusion becomes, for example, one of the most important technical fields.

In order to realize a stable semiconductor processing process, important is temperature control technology for maintaining a processing object within an appropriate temperature range during processings. However, a conventional technique of measuring temperature by using a thermocouple is not suitable to adopt semiconductor wafer processing processes for mass-producing the semiconductor devices. Consequently, a technique for detecting the temperature of the semiconductor wafers in a non-contact or non-invasive manner is demanded.

As such a technique, it is conceivable to use a radiation thermometer that detects the temperature by detecting an amount of heat emitted from the semiconductor wafer. However, a process of processing the semiconductor wafers to manufacture devices is generally restricted by melting points or the like of various materials. In a process of manufacturing a typical semiconductor device currently in practice, temperature of the semiconductor wafer is controlled to a value around 500° C. or a value equal to or less than this. At such temperature, a problem arises about stable detection of the temperature by the radiation thermometer becoming difficult.

As an alternative technique of the technique using such a radiation thermometer, bandedge evaluation technology, which stably detects temperature by using temperature dependence of a frequency of a region edge in a frequency (wavelength) range of an electromagnetic wave absorbed by the semiconductor, has received a lot of attention in recent years. This technology is technology for detecting the temperature of a semiconductor wafer by measuring a spectrum of light passing through or scattered and reflected by the semiconductor wafer to evaluate an absorption edge of the spectrum.

Here, that the absorption edge of the light spectrum depends on the temperature is for the reason that as the temperature increases, a bandgap of the semiconductor becomes smaller and allows excitation of lower-energy photons and, as a result, the absorption edge is shifted on a longer wavelength side. It is known that the bandgap of the semiconductor decreases approximately in proportion temperature within higher temperature than vicinity of the device temperature. Consequently, using the bandedge evaluation technology makes it possible to detect the temperature of the semiconductor wafer with relatively high accuracy even in a temperature range of 500° C. or lower, the temperature range being difficult to detect stably with the radiation thermometer.

In a manufacturing apparatus for manufacturing a semiconductor device such as a dry etching apparatus, known have been National Publication JA 2003-519380 (Patent Document 1) and Japanese Patent Application Laid-open No. 2018-73962 (Patent Document 2) disclosing a technique in which the temperature of the semiconductor wafer is detected with high accuracy using the above-described bandedge evaluation technique. In Patent Document 1, bandedges are evaluated by providing a dedicated infrared light source. In Patent Document 2, bandedges are evaluated by using, as a light source, an infrared light lamp that heats the semiconductor wafer to be processed.

When evaluations are made by using transmitted light from the semiconductor wafer, interference between a light source and a heat source, a device space, and the like become problems. Further, when evaluations are made by using scattering reflection light, a large hole(s) is required for performing spectrum and light projection simultaneously, so that it may be difficult to ensure temperature uniformity of a substrate. Consequently, by using a configuration as shown in Patent Document 2 in which an infrared light lamp for heating the semiconductor wafer to be processed is used as a light source, the temperature of the semiconductor wafer can be stably detected.

Further, U.S. Pat. No. 9,239,265 (Patent Document 3) discloses a method of determining a bandedge by using a first-order differentiation or the like after standardizing by dividing a detected spectrum by a spectrum of only a light source.

### RELATED ART DOCUMENTS

### Patent Documents

Patent Document 1: National publication JA 2003-519380
Patent Document 2: Japanese Patent Application Laid-open No. 2018-73962
Patent Document 3: U.S. Pat. No. 9,239,265 Specification

### Non-Patent Documents

Non-Patent Document 1: W. E. Hoke et al., J. Vac. Sci. Technol. B28, C3F5 (2010)

### SUMMARY OF THE INVENTION

### Problems to be Solved by the Invention

However, in the above-described conventional technique, problems have arisen due to insufficient consideration of the following points.

That is, when an electromagnetic wave or light irradiated to heat a semiconductor wafer (hereinafter also simply referred to as a wafer) is used to detect temperature of the wafer, an intensity and a spectrum of the irradiated light leads to depending on a condition of heating the wafer. Consequently, it is difficult to stably detect the temperature with the conventional method, and the temperature of the wafer may not be detected with high accuracy.

In addition, in the method of the conventional technique, a wafer having a configuration equivalent to that of a temperature measurement target is prepared in advance, and correlation data between the temperature of the wafer and an absorption edge wavelength, for example, a calibration formula is calculated. Then, the temperature is detected based on an absorption edge wavelength obtained from data detected from a wafer as an actual target and the above-mentioned correlation data. However, this technique needs to calculate the correlation data in advance for each wafer heating condition.

As a specific example, when a single semiconductor processing apparatus is used to process a plurality of types of wafers, a user of the semiconductor processing apparatus needs, in advance, to calculate the above-mentioned correlation data in a form capable of reusing the semiconductor processing apparatus for each condition of wafer types and different processings to be supposed to use, and needs to store it in the semiconductor processing apparatus. In this case, an operation time for manufacturing the semiconductor device by the semiconductor processing apparatus may be shortened, or flexible use of the apparatus may be impaired.

Furthermore, the above-mentioned technique, for example, W. E. Hoke et al., J. Vac. Sci. Technol. B 28, C3F5 (2010) (Non-patent Document 1) discloses that the measured spectra are standardized at the maximum value and the minimum value of the light intensity. However, in standardizing, a wavelength at which the light intensity reaches its maximum value depends on an intensity of irradiated light, a substrate resistance of the wafer, a film formed on the wafer, and the like, so that a range of wavelengths in standardizing needs to be defined somehow. However, the appropriate range of the wavelengths has not been considered in detail in the conventional technique.

As a result of them, the conventional technique described above has a problem about lowering of accuracy of wafer temperature detection or a reduction in wafer processing yield. Alternatively, in a semiconductor processing apparatus, no consideration has been given to a problem abut a loss of an operating time for processing the wafers to manufacture the semiconductor device or a reduction in processing efficiency.

One of objects of the present invention is to provide a temperature detector capable of detecting temperature of a semiconductor wafer with high accuracy. Alternatively, an object is to provide a semiconductor processing apparatus capable of improving processing efficiency.

The above and other objects and novel features of the present invention will become apparent from the description of the present specification and the accompanying drawings.

### Means for Solving the Problems

A brief outline of representative embodiments in the invention disclosed in the present application is as follows.

A temperature detector according to a representative embodiment of the present invention includes a light source irradiating a semiconductor wafer with light, a spectroscope dispersing transmitted light or scattered reflection light generated from the semiconductor wafer according to irradiation of the light, and a photodetector measuring the light dispersed by the photodetector, and a controller determining a bandedge wavelength by numerically processing a first spectrum obtained by the photodetector and detecting temperature of the semiconductor wafer from the bandedge wavelength. The controller performs a standardization processing, a bandedge determination processing, and a temperature calculation processing. In the standardization processing, the controller uses as a local minimum wavelength a wavelength corresponding to the bandgap energy of the semiconductor at absolute zero to determine as a local minimum value the minimum value of the light intensity in a wavelength region shorter than the minimum wavelength, and uses as a first maximum wavelength a wavelength corresponding to a difference between the bandgap energy and the thermal energy of the semiconductor at the highest temperature assumed as a temperature measurement range to determine as a local maximum value a value obtained by taking a difference of the local minimum value from the maximum value of the light intensity in a wavelength range shorter than the first maximum wavelength, and performs a difference processing with the local minimum value with respect to the first spectrum to divide it by the local maximum value, thereby standardizing it. In the bandedge determination processing, the controller determines a bandedge wavelength based on the second spectrum obtained in the standardization processing. In the temperature calculation processing, the controller detects temperature of the semiconductor wafer by comparing previously acquired correlation data between values of temperature and the bandedge wavelength with the bandedge wavelength specified in the bandedge determination processing.

### Effects of the Invention

If an effect(s) obtained by the representative embodiment of the present invention is easily described, it becomes possible to detect the temperature of the semiconductor wafer with high accuracy.

### BRIEF DESCRIPTION OF THE DRAWINGS

FIG. 1A is a sectional view showing a schematic configuration example of a semiconductor processing apparatus according to a first embodiment;

FIG. 1B is a sectional view showing a more detailed configuration example of the semiconductor processing apparatus shown in FIG. 1A;

FIG. 2 is a graph showing one example of a spectrum of light passing through a semiconductor wafer when the semiconductor wafer is at a predetermined temperature in an etching apparatus shown in FIG. 1B;

FIG. 3 is a graph showing an example of a spectrum obtained by standardizing a spectrum of a high-resistance wafer in the spectrum shown in FIG. 2 by a method of the first embodiment in the etching apparatus shown in FIG. 1B;

FIG. 4 is a graph showing an example of a spectrum obtained by standardizing a spectrum of a high-resistance wafer in the spectrum shown in FIG. 2 in the etching apparatus shown in FIG. 1B by a method disclosed in Patent Document 3;

FIG. 5 is a graph showing an example of a result of comparing standardized spectrum shown in FIG. 3 and a standardize spectrum shown in FIG. 4;

FIG. 6 is a graph showing part of the standardized spectrum shown in FIG. 3, and is a graph for explaining one example of a method of specifying a bandedge wavelength;

FIG. 7 is a graph showing one example of comparing temperature of a semiconductor wafer detected by using the method of the first embodiment and temperature of the semiconductor wafer detected by using a contact thermocouple when output power or input power of an infrared light lamp is varied between 40% and 70% in the etching apparatus shown in FIG. 1B; 3

FIG. 8 is a graph showing, for different types of semiconductor wafers, one example of comparing temperature of the semiconductor wafer detected by the method of the first embodiment and temperature of the semiconductor wafer detected by using a thermocouple;

FIG. 9 is a graph showing, for low resistance wafers, one example of comparing temperature of the semiconductor wafer detected by using the method of the first embodiment and temperature of the semiconductor wafer detected by using a thermocouple for low resistance wafers in the etching apparatus shown in FIG. 1B;

FIG. 10 is a graph showing part of the standardized spectrum shown in FIG. 3 in a semiconductor processing apparatus according to a second embodiment, and is a graph explaining one example of a method of specifying a bandedge wavelength;

FIG. 11 is a graph showing one example of comparing wafer temperature obtained from the bandedge wavelength specified by the method shown in FIG. 10 and the wafer temperature obtained by using the thermocouple;

FIG. 12 is a sectional view showing a schematic configuration example of a semiconductor processing apparatus according to a third embodiment;

FIG. 13 is a graph showing one example of a standardized spectrum distribution obtained from a heating apparatus shown in FIG. 12;

FIG. 14 is a graph showing one example of comparing temperature of a wafer obtained by setting a wavelength having an integrated value of 0.55 times the maximum area as a bandedge wavelength and temperature of a hot plate in the heating apparatus shown in FIG. 2;

FIG. 15 is a graph showing one example of a standardized spectrum distribution obtained from the heating apparatus shown in FIG. 12, and a graph explaining one example of a method of specifying a bandedge wavelength;

FIG. 16 a graph showing one example of comparing temperature of a wafer obtained by setting a bandedge wavelength from a wavelength difference between a reference wavelength at reference temperature and a measurement wavelength at measurement temperature and temperature of the hot plate in the heating apparatus shown in FIG. 12;

FIG. 17 is a graph showing one example of a standardized spectrum distribution obtained from the heating apparatus shown in FIG. 12, and is a graph explaining one example of a method of specifying a bandedge wavelength; and

FIG. 18 is a graph showing one example in which, after standardizing by using the maximum value of a first spectrum at reference temperature, wafer temperature obtained by setting a different wavelength between a reference wavelength at the reference temperature and a measurement wavelength at measurement temperature as a bandedge wavelength is compared with temperature of the hot plate in the heating apparatus shown in FIG. 12.

### DETAILED DESCRIPTION OF PREFERRED EMBODIMENTS

Hereinafter, embodiments of the present invention will be described in detail based on the drawings. Incidentally, throughout all the drawings for explaining the embodiments, the same members are denoted by the same reference numerals in principle, and a repetitive description thereof will be omitted.

### Outline of Embodiment

As described above, when an electromagnetic wave or light irradiated to heat a semiconductor wafer is used to detect temperature of the wafer, an intensity and a spectrum of the irradiated light lead to depending on conditions for heating the wafer. Consequently, a conventional method has a problem in which it becomes difficult to stably detect the temperature of the wafer with high accuracy.

Further, in the conventional method, for each wafer heating condition, needed is work of: preparing a wafer having a configuration equivalent to that of an object of temperature measurement in advance; and calculating correlation data between the temperature and an absorption edge (bandedge) wavelength, for example, calculating a calibration formula. Consequently, a problem has arisen about a shortage of time during which a semiconductor processing apparatus is operated for the purpose of manufacturing semiconductor devices and about a loss of flexible use of the apparatus. Furthermore, in standardizing a spectrum of measured transmitted light in a process of detecting temperature, a conventional technique has not considered an appropriate range of wavelengths to be standardized.

As a result of them, in the conventional technique, a problem has arisen about lowering of accuracy of wafer temperature detection, a reduction in a yield of a wafer processing or about a loss of the operation time of the semiconductor processing apparatus for processing the wafers to manufacture the semiconductor devices and a reduction in processing efficiency. In order to solve a problem, the inventors and the like has used the infrared light, which is used for heating the wafer, to detect the temperature and has evaluated a relationship between the intensity and the temperature of the light irradiated from the wafer during the heating by using as targets a plurality of types of wafers including different structures and types of surface films or different wafer structures.

As a result, a shape of the spectrum of the transmitted light varies greatly depending on the intensity of the light irradiating the wafer and the type of wafer, so that it has proved difficult to stably detect the wafer temperature with high accuracy in the conventional technique. Meanwhile, the inventors have restricted a suitable wavelength band to perform a standardization processing, obtained common correlation data between a value and temperature of the bandedge wavelength by heating a single type of wafer under a single heating condition, thereby having obtained finding of capable of stably detecting the temperature of wafers different in types or in heating condition with high accuracy by using the common correlation data.

The present invention has been obtained based on such findings. Specifically, a first spectrum obtained by measuring the light passing through the wafer is smoothed and standardized within an appropriately defined range of the wavelength. Then, by first differentiating a second spectrum obtained by the smoothing and standardizing with respect to the wavelength, a wavelength at which a first differentiated value becomes the maximum is calculated and, in a longer wavelength range including the wavelength, a wavelength having a particular intensity is defined as a bandedge wavelength.

In manufacturing the semiconductor device, prior to an operation of a manufacturing apparatus, a single type of wafer is used in advance, and correlation data between the temperature and the value of the bandedge wavelength of the light passing through the wafer, for example, as calibration formula is obtained. In actually manufacturing the semiconductor device, the light passing through the wafer is measured during the operation of processing the wafer by using the manufacturing apparatus, the bandedge wavelength is specified by the above-mentioned method, and the specified bandedge wavelength and the above-mentioned correlation data obtained in advance is compared to detect or determine the wafer temperature.

In determining the bandedge wavelength, two points are taken on the standardized second spectrum in a wavelength range in which a temperature change in bandgap is reflected, and an intercept of a straight line passing through the two points and a wavelength axis may be defined as a bandedge wavelength. It is desirable to select such two points so that a difference between their wavelengths is as large as possible. Alternatively, the standardized second spectrum is integrated with respect to the wavelength, and a wavelength at which an integrated value becomes a predetermined reference value may be defined as a bandedge wavelength.

Since a bandedge wavelength corresponding to an absorption edge of the semiconductor strongly depends on the bandgap of the semiconductor, the wavelength range suitable for normalization should be within a range as narrow as possible and a wide range enough to reflect a change in bandgap due to the temperature as much as possible so that the bandedge wavelength can be stably detected. Therefore, from the first spectrum obtained by the measurement, the local minimum value and the local maximum value of the light intensity are determined, the first spectrum is subjected to a difference processing with the local minimum value and then divided by the maximum value, and the first spectrum is standardized to obtain the standardized second spectrum.

Here, the local minimum value is set to the minimum value of a light intensity in a range of wavelengths shorter than a wavelength corresponding to the bandgap at absolute zero in the first spectrum. The reason for this is that since semiconductors absorb light in such a wavelength range, a spectrum of transmitted light cannot be obtained in principle. Meanwhile, the local maximum value is set, by using as the maximum wavelength a wavelength corresponding to a difference between a bandgap and thermal energy of the semiconductor at the highest temperature assumed as a temperature measurement range and thermal energy, to a value obtained by subtracting the above-mentioned local minimum value from the maximum value of the light intensity in a range of wavelengths shorter than the maximum wavelength. The reason for this is that the bandgap of the semiconductor becomes smaller as the temperature rises and an influence on the absorption edge is considered to be an energy range shifted only by an amount of thermal energy at that temperature from the bandgap at that temperature.

### First Embodiment

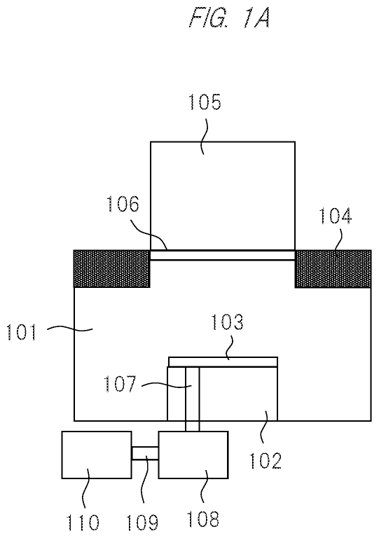

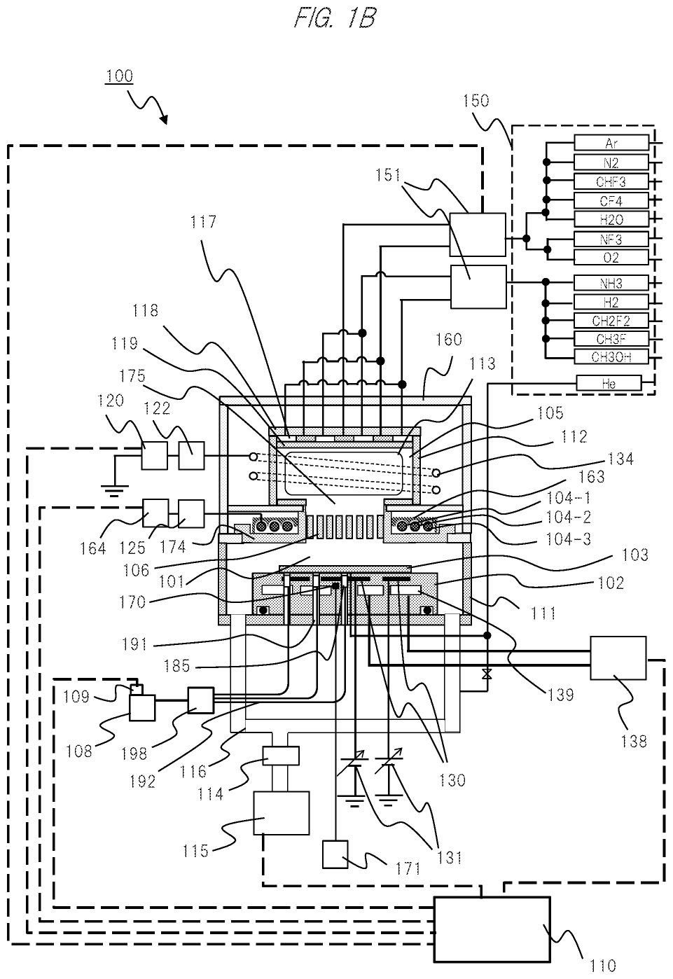

A first embodiment will be described with reference to FIGS. 1 to 8. The first embodiment relates to temperature evaluation of a semiconductor wafer during heating in an etching apparatus, that is, a semiconductor processing apparatus or a semiconductor manufacturing apparatus in which a heating light source of an infrared light lamp is installed.

### Schematic Configuration of Semiconductor Device

FIG. 1A is a sectional view showing a schematic configuration example of a semiconductor processing apparatus according to a first embodiment. A semiconductor processing apparatus is, for example, an etching apparatus or the like. The semiconductor processing apparatus includes a processing chamber 101 for processing a semiconductor wafer 103, a wafer stage 102, an infrared light lamp 104 as a light source or a heating light source, a plasma source 105, a plate member 106, and an optical path 107, a spectroscope 108, a photodetector 109, and a controller 110. The wafer stage 102 is installed in the processing chamber 101 and mounts thereon a semiconductor wafer 103 which is an object to be processed and is also an object to be measured of temperature.

The plasma source 105 is installed above the wafer stage 102 and forms plasma by using processing gas. The plate member 106 is installed between the processing chamber 101 and the plasma source 105 and includes a plurality of through-holes through which the processing gas is introduced. The infrared light lamp 104 is installed so as to surround an outer periphery of the plate member 106 and heats the wafer 103 by irradiating the wafer 103 with light. The optical path 107 is attached inside the wafer stage 102.

The spectroscope 108 disperses transmitted light or scattered reflection light generated from the wafer 103 in response to irradiation of light from the infrared light lamp 104, in this example, transmitted light transmitted via the optical path 107. The photodetector 109 measures light split by the spectroscope 108. The controller 110 is implemented by, for example, a computer including a processor and a memory, and controls the entire semiconductor processing apparatus.

As one of them, the controller 110 identifies a bandedge wavelength by numerically processing a spectrum (first spectrum) obtained by the photodetector 109, and detects temperature of the wafer 103 from the bandedge wavelength. Further, the controller 110 may control the temperature of the wafer 103 by feeding back a detection result of the temperature of the wafer 103 and controlling the infrared light lamps 104 and the like.

In FIG. 1A, the infrared light lamps 104 are arranged in a donut shape, but they may be installed directly above or beside the wafer stage 102 depending on the purpose as long as a transmitted light spectrum can be obtained. Also, here, the infrared light from the infrared lamp 104, which is a heating source, has been used as a light source, but an external infrared light source may be installed on an opposite side of the spectroscope 108 with the wafer 103 interposed therebetween. In addition, an external infrared light source is installed on the same side as the spectrometer 108 with reference to the wafer 103, and the bandedge wavelength may be specified based on the spectrum of the scattered reflection light obtained by irradiating a back surface of the wafer 103 with light via the optical path 107.

Also, in FIG. 1A, the infrared light lamp 104, the spectroscope 108, the photodetector 109, and the controller 110 constitute a temperature detector for detecting temperature of the wafer 103. In an example of FIG. 1A, the temperature detector is incorporated in the etching apparatus, but may be incorporated in various semiconductor processing apparatuses or semiconductor manufacturing apparatuses without being limited to the etching apparatus. Furthermore, it is also possible to use the temperature detector alone.

FIG. 1B is a sectional view showing a more detailed configuration example of the semiconductor processing apparatus shown in FIG. 1A. The semiconductor processing apparatus shown in FIG. 1B is an etching apparatus 100. In FIG. 1B, the processing chamber 101 is a chamber arranged in a base chamber 111 forming a lower portion of a vacuum container, and the wafer stage 102 having the wafer 103 mounted thereon is installed in the chamber. Further, a discharge chamber 105 is a chamber arranged in a cylindrical quartz chamber 112 forming an upper portion of the vacuum container, and plasma 113 can be generated in the chamber by an ICP discharge method. The discharge chamber 105 is also a plasma source located above the processing chamber 101 in FIG. 1A.

An ICP coil 134 is installed outside the quartz chamber 112. A high frequency power supply 120 for plasma generation is connected to the ICP coil 134 through a matching box 122. A frequency band of several tens MHz such as 13.56 MHz is used as a frequency of high frequency power. At a top of the quartz chamber 112, a top plate 118, which constitutes a top of the vacuum container and a lid of the discharge chamber (plasma source) 105, is rested so as to airtightly seal a space between an atmosphere outside the quartz chamber 112 and a pressure-reduced interior. A gas dispersion plate 117 and a shower plate 119 are installed below the top plate 118 and above the discharge chamber 105. The processing gas is introduced into the processing chamber 101 through an interior of the discharge chamber 105 via the gas distribution plate 117 and the shower plate 119.

The processing gas flows through gas supply pipelines prepared for each gas type, and a flow rate per unit time (flow velocity) is adjusted for each type flowing in the pipes by respective mass flow controllers arranged on these pipes. In an example of FIG. 1B, these pipes and the mass flow controllers on the respective pipes form, as a mass flow controller unit 150 arranged inside one box, the quartz chamber 112 forming the upper part of the vacuum container, and eventually is connected to the discharge chamber 105.

In addition, at least one gas distributor 151 is arranged on a pipe coupling the mass flow controller unit 150 and the discharge chamber 105. A pipe extending from the gas distributor 151 is connected to the vicinity of a center of the discharge chamber 105 having a cylindrical shape and its outer periphery. Consequently, a flow rate and a composition of each gas supplied to a central portion and an outer peripheral portion of the interior of the discharge chamber 105 located below these connection points can be independently controlled and supplied, and a radical space distribution in the discharge chamber 105 can be finely adjusted.

Incidentally, in the example of FIG. 1B, inside the mass flow controller unit 150, the respective gas pipes of NH3, H2, CH2F2, CH3F, CH3OH, O2, NF3, Ar, N2, CHF3, CF4, and H2O as processing gases and the mass flow controllers are arranged in parallel. However, in the etching apparatus 100, gases other than the above gases may be used according to the specifications required for processing the wafer 103.

A lower portion of the processing chamber 101 is connected to an exhaust pump 115 via a vacuum exhaust pipe 116 in order to reduce a pressure inside the processing chamber 101. The exhaust pump 115 is composed of, for example, a turbomolecular pump, a mechanical booster pump, or a dry pump. Furthermore, in order to adjust the pressure inside the processing chamber 101 and the discharge chamber 105, a pressure regulating valve 114 is arranged on the vacuum exhaust pipe 116 on an upstream side of the exhaust pump 115, the pressure regulating valve 114 having a value for adjusting an amount of exhaust per unit time (flow rate of exhaust) by changing a cross-sectional area of the vacuum exhaust pipe 116.

Above the wafer stage 102, arranged is a flow path 175 to communicate between the discharge chamber 105 and the processing chamber 101 and to flow particles in the plasma 113 formed in the discharge chamber 105 toward the processing chamber 101. Above the processing chamber 101 and below the ICP coil 134, an infrared light lamp unit for heating the wafer 103 is arranged in a ring shape so as to surround the flow path 175 on an outer peripheral side thereof. The infrared light lamp unit is mainly composed of the infrared light lamp 104, a reflector 163 that reflects light or electromagnetic waves from the infrared light lamp 104, and a translucent member such as quartz. It includes an infrared light transmission window 174 having a portion forming a ceiling surface of the processing chamber 101 below the infrared light lamp 104 and a portion forming an inner peripheral side wall of the flow path 175.

Used as the infrared light lamp 104 is a lamp having a circle shape (circular shape) surrounding the flow path 175 like a ring on an outer peripheral side thereof. Incidentally, the light or electromagnetic waves emitted from the infrared light lamp 104 emit light mainly in an infrared light range from a visible light range. More specifically, the infrared light lamp 104 includes infrared light lamps 104-1, 104-2, and 104-3 triply arranged concentrically from an inner peripheral side toward an outer peripheral side in a horizontal direction. However, the present embodiment is not limited to a triplex configuration, and may be a double configuration, a quadruple configuration, or the like. The reflector 163 is installed above the infrared light lamp 104 and reflects the light or electromagnetic waves emitted from the infrared light lamp 104 downward, that is, toward the wafer 103 mounted on the wafer stage 102.

An infrared light lamp power source 164 is electrically connected to the infrared light lamp 104, and a high-frequency cut filter 125 is installed between the infrared light lamp power source and the infrared light lamp so that noise associated with plasma generation high-frequency power does not flow into the infrared light lamp power source. Further, the infrared lamp power source 164 has a function of independently controlling power supplied to the infrared lamps 104-1, 104-2, and 104-3, thereby adjusting a radial distribution of an amount of heating the wafer 103. Incidentally, in FIG. 1B, illustration of a part of wirings associated with the function is omitted.

Incidentally, a plate member 106 having a plurality of through-holes or slits formed at predetermined positions, more specifically, a slit plate is installed in the path flow 175 positioned at a central portion in a region surrounded by the infrared light lamp unit. The plate member 106 inhibits a passage of charged particles such as ions and electrons in the plasma 113 formed in the discharge chamber 105 inside the quartz chamber 112 by means of the plurality of through-holes or slits, and causes neutral gases and neutral radicals to pass, introduces them into the processing chamber 101, and supplies them onto the wafer 103.

Arranged inside the wafer stage 102 is a refrigerant flow path 139 supplied to cool a metal base material of the wafer stage 102. The flow path 139 is connected to a chiller 138, which is a refrigerant temperature adjusting mechanism, and is configured so that a refrigerant whose temperature has been adjusted to a value within a predetermined range is circulated and supplied inside. Further, in order to fix the wafer 103 by electrostatic adsorption, plate-shaped electrode plates 130 are embedded inside the wafer stage 102, and a DC power source 131 is connected to each electrode plate.

During a processing of the wafer 103, in order to efficiently adjust the temperature of the wafer 103 to a value within a range suitable for the processing, gas having a heat transference such as He gas is supplied between the back surface of the wafer 103 and the wafer stage 102. Further, in order to prevent the back surface of the wafer 103 from being damaged when the wafer 103 is heated or cooled while the wafer 103 is adsorbed on the upper surface of the wafer stage 102, the upper surface of the wafer stage 102 is coated with a resin such as polyimide.

A thermocouple 170 for detecting the temperature of the wafer stage 102 is provided inside the wafer stage 102, and this thermocouple 170 is connected to a thermocouple thermometer 171. Furthermore, a plurality of (three in this example) quartz rods 185 and through-holes 191 are arranged inside the wafer stage 102 so as to penetrate the base material. The quartz rod 185 and the through-hole 191 constitute: a light receiver for receiving light emitted from the infrared light lamp 104 and transmitted through the wafer 103; and an optical path 107 shown in FIG. 1A and transmitting the received light. An optical fiber 192 connected to the quartz rod 185 is attached in the through-hole 191. In the example of FIG. 1B, the through-hole 191 is arranged at each of three locations on the wafer stage 102, which correspond to three locations: the vicinity of the central portion of the wafer 103, the vicinity of a middle portion in a radial direction of the wafer, and the vicinity of an outer circumference of the wafer.

The light irradiated from the infrared light lamp 104, passing through an infrared light transmission window 174, and irradiated to the wafer 103 on the wafer stage 102 inside the processing chamber 101 transmits the wafer 103, is incident on the upper surface of the quartz rod 185 inside the through-hole 191, and received by the photodetector. The received light is transmitted through the optical fiber 192, which is connected to the quartz rod 185, to the spectroscope 108 connected to the other end of the optical fiber 192, and is dispersed per two or more than predetermined wavelengths. Then, the dispersed light is sent to the photodetector 109. Then, the photodetector 109 measures the light intensity of each wavelength, thereby obtaining data of a spectrum (first spectrum) representing a light intensity of each wavelength.

Further, in the example of FIG. 1B, an optical multiplexer 198 is installed in the middle of the optical fiber 192, and is configured so as to be switchable about which point of a central portion, a middle portion, or an outer peripheral portion of the wafer 103 the light is dispersed at. Incidentally, adopted may be a configuration in which a set of the spectrometer 108 and the photodetector 109 is provided for each of the central portion, the middle portion, and the outer peripheral portion and, at the same time, spectral data is detected from the light received by the receivers at three locations.

Further, the etching apparatus 100 shown in FIG. 1B includes a controller 110 that controls the etching apparatus 100 as a whole. The controller 110 controls an operation and output magnitude of each component such as a high-frequency power supply 120, a matching box 122, a DC power supply 131, a pressure regulation valve 114, an exhaust pump 115, a mass flow controller unit 150, a gas distributor 151, an infrared light lamp power supply 164, and a unshown gate valve.

Further, the controller 110 also receives outputs of the thermocouple thermometer 171 and the photodetector 109, and generates a command signal for adjusting the operations of the power supply, valves, and pumps, etc. to operations suitable to the processings based on measurement data represented by the output. Furthermore, the controller 110 may change and adjust the processing condition such as a type and a composition of the gas introduced into the processing chamber 101 or discharge chamber 105 or pressure in the vacuum container in response to the temperature of the wafer 103 which has been detected based on the signal from the photodetector 109.

The temperature of the wafer stage 102 is desirably controlled by combining the infrared lamp 104 and the chiller 138. At this time, the controller 110 may control the temperature of the wafer stage 102 having a correlation with the temperature of the wafer 103 by complimentarily compounding the temperature of the wafer 103 obtained based on the signal from the photodetector 109 and the temperature of the wafer state 102 detected by the thermocouple thermometer 171. Further, the controller 110 may adjust the temperature of the wafer 103 by feeding back the temperature of the wafer 103 obtained based on the signal from the photodetector 109 to control the infrared light lamp power source 164.

In processing the wafer 103, for example, argon is introduced into the processing chamber 101 to heat the wafer 103. However, since an absorption wavelength of light due to gas molecules exists on a long wavelength side in comparison with the absorption-edge wavelength of the semiconductor, an effect on temperature detection based on the bandedge wavelength as shown in the first embodiment is small. Therefore, a plurality of types of gas can be used for the introduction into the processing chamber 101 and for heating the wafer 103.

In the etching apparatus 100 shown in FIG. 1B, the wafer 103 placed on the wafer stage 102 in the decompressed processing chamber 101 is absorbed and held by using electrostatic on the wafer stage 102. Thereafter, the processing gas is supplied into the discharge chamber 105 and the plasma 113 is formed by using the processing gas inside the discharge chamber 105. Neutral particles such as active species (radicals) in the plasma 113 are introduced into the processing chamber 101 from the discharge chamber 105 through the through-holes or slits of the plate member 106, and adhere to a surface of a film to be processed on the upper surface of the wafer 103, thereby forming a compound layer.

When the processing gas or plasma particles in the processing chamber 101 is exhausted by an operation of the exhaust pump 115, Ar gas, which is an inert gas, is introduced into the processing chamber 101 through the discharge chamber 105, and an interior of the processing chamber 101 is adjusted to a pressure range suitable for heating the wafer 103. Thereafter, power is supplied to the infrared lamp 104 from the infrared lamp power source 164, and the wafer 103 is heated by the light emitted from the infrared lamp 104 being irradiated onto the wafer 103. When the temperature of the wafer 103 reaches a value within a predetermined range, a compound layer sublimes and desorbs and is removed from a surface of the film layer to be processed, and is discharged outside the processing chamber 101 by the exhaust pump 115 that continues to operate. Consequently, the etching of the film layer to be processed proceeds.

The light irradiated onto the wafer 103 and transmitted through the wafer 103 is received by a light receiver including the quartz rod 185 and is transmitted to the spectroscope 108, and the dispersed light is measured by the photodetector 109, and data of a spectrum (first spectrum) representing a light intensity for each wavelength is obtained. The controller 110 identifies the bandedge wavelength of the light based on the spectrum data.

Then, the controller 110 compares the specified bandedge wavelength and the preliminarily obtained correlation data between the value of the bandedge wavelength and the temperature of the wafer 103, for example, a calibration formula, thereby detecting the temperature of the wafer 103 corresponding to the specified bandedge wavelength. Furthermore, the controller 110 increases or decreases the output of the infrared light lamp 104 or the setting of the refrigerant temperature adjusted by the chiller 138 based on information on the detected temperature, thereby adjusting the temperature of the wafer 103 so as to be within a range suitable for desorbing and removing the above-mentioned compound layer.

### Details of Temperature Detection Method

Hereinafter, detailed will be a method in which the controller 110 identifies the bandedge wavelength by numerically processing the spectrum (first spectrum) obtained by the photodetector 109 and detects the temperature of the semiconductor wafer 103 from the bandedge wavelength.

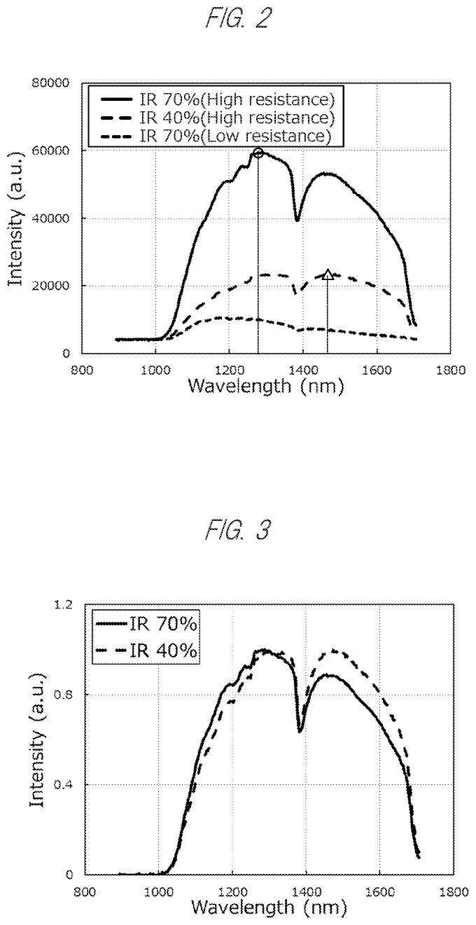

FIG. 2 is a graph showing an example of a spectrum of light passing through a semiconductor wafer when the semiconductor wafer is at a predetermined temperature in the etching apparatus shown in FIG. 1B. That is, in FIG. 2, shown is one example of a spectrum (first spectrum) obtained by measuring the light passing through the wafer 103 by the photodetector 109 when the semiconductor wafer 103 made of silicon is mounted on the wafer stage 102 of the etching apparatus 100 and is heated by the infrared light lamp 104. In FIG. 2, a horizontal axis is a wavelength and a vertical axis is a light intensity. Specifically, FIG. 2 shows a spectrum when the temperature of the wafer 103 is 60° C.

In FIG. 2, the used semiconductor wafer 103 has a resistivity of 30 Ωcm (hereinafter referred to as a high resistance wafer) and 0.019 Ωcm (hereinafter referred to as a low resistance wafer). Output power or input power of the infrared light lamp 104 is set at 70% and 40% of the maximum. In FIG. 2, a depression seen near 1380 nm is an absorption component due to moisture of the light receiver that receives the transmitted light passing through the wafer 103 arranged inside the wafer stage 102, that is, the quartz rod 185 in FIG. 1B, and an amount of absorption thereof is reduced by using anhydrous quartz.

As shown in FIG. 2, even if the temperature of the wafer 103 is the same and when the intensity of the light irradiated from the infrared light lamp 104 and the type of the wafer 103 are different, a shape of the transmitted light spectrum will be significantly different. In particular, when the used wafer 103 is a high resistance wafer, the maximum light intensity becomes around 1280 nm as indicated by a circle when the output power of the infrared light lamp 104 is 70%, while in a case of 40%, it becomes around 1450 nm as indicated by a triangle mark. In other words, depending on the output power of the infrared light lamp 104, eventually the intensity of the radiated light, and the type of the wafer 103, that is, a structure and a configuration, the wavelength having the maximum light intensity in the spectrum obtained by the photodetector 109 is becomes different.

For this reason, for example, when the standardization is performed by using the local maximum value or local minimum value of the light intensity as in Non-Patent Document 1, it is necessary to set an appropriate wavelength range to determine the local maximum value or local minimum value. In addition, the spectrum, which is measured by the light emitted from the infrared light lamp 104 being divided into predetermined wavelengths and being absorbed on the optical path until being detected as a spectrum, also varies depending on the intensity of the light from the infrared light lamp 104. Consequently, the standardization by using the spectrum of the light emitted from the infrared light lamp 104 as described in Patent Document 2 is not easy. That is, for the light from the infrared light lamp 104 whose light intensity varies depending on a condition such as target temperature of the wafer 103, a spectrum to be a reference is required for each condition.

### Regarding Standardization Processing

FIG. 3 is a graph showing one example of a spectrum obtained by standardizing the spectrum of the high resistance wafer in the spectrum shown in FIG. 2 by the method of the first embodiment in the etching apparatus shown in FIG. 1B. That is, FIG. 3 shows two spectra (second spectrum) obtained by the controller 110 targeting two high-resistance-wafer spectra (first spectra) shown in FIG. 2 to perform the respective standardization processings to the two spectra. FIG. 4 is a graph showing one example of a spectrum obtained by standardizing a high-resistance-wafer spectrum in the spectrum shown in FIG. 2 by the method disclosed in Patent Document 3 in the etching apparatus shown in FIG. 1B.

In standardizing by the method of the first embodiment, first, the local minimum value and the local maximum value are determined. Regarding the local minimum, a bandgap of silicon at absolute zero is 1.17 eV, which corresponds to a wavelength of 1060 nm. Consequently, in FIG. 2, the controller 110 determines the minimum value of the light intensity in a wavelength region shorter than 1060 nm, specifically, determines an average value of a light intensity in a wavelength region of 1000 nm or less, for example, as the local minimum value. Incidentally, in the specification, 1060 nm, which is a wavelength corresponding to a bandgap of silicon at absolute zero, is referred to as a local minimum wavelength.

Meanwhile, regarding the local maximum value, the highest temperature reached by heating the wafer 103 is around 500° C. at most. In other words, the highest temperature assumed as a temperature measurement range is around 500° C. The bandgap of silicon at 500° C. is 1.01 eV, which corresponds to a wavelength of 1230 nm. In the specification, 1230 nm, which is a wavelength corresponding to a bandgap of silicon at the highest temperature, is referred to as a local maximum wavelength.

Here, the bandgap widens due to thermal energy as the temperature rises. Therefore, the controller 110 determines, as the maximum wavelength (first maximum wavelength), a wavelength of 1320 nm corresponding to 0.94 eV, which is a difference between a band gap of 1.01 eV at 500° C. and a thermal energy of 0.07 eV at 500° C., and determines, as the local maximum value, a value by taking the difference of the above-mentioned local minimum value from the maximum value of a light intensity in a wavelength region shorter than the maximum wavelength.

As a specific example, in FIG. 2, the local maximum value in a case of the high resistance wafer and 70% is determined as a value obtained by taking a difference between the maximum value of a light intensity indicated by a circle and the local minimum value of a light intensity determined in a wavelength region of 1000 nm or less. Meanwhile, the local maximum value in a case of the high resistance wafer and 40% is determined based on not a light intensity around 1450 nm indicated by a triangle mark but the maximum light intensity in a wavelength region shorter than the maximum wavelength (first maximum wavelength) of 1320 nm.

The controller 110 performs the standardization by using the local minimum and the local maximum determined in this way. Specifically, before standardizing, the controller 110 first performs a smoothing processing to the spectrum (first spectrum) obtained from the photodetector 109 by a moving average to such a degree that the maximum value of the spectrum can be determined. The spectrum shown in FIG. 2 is, more particularly, after the smoothing processing has been performed.

Then, the controller 110 performs a difference processing between the spectrum (first spectrum) obtained from the photodetector 109, more specifically, the smoothed spectrum and the above-mentioned local minimum value, and is divided by the local maximum, thereby standardizing the first spectrum. That is, the standardization is performed so that the local minimum value is 0 and the local maximum value is 1.0. As a result, a standardized spectrum (second spectrum) as shown in FIG. 3 is obtained.

Meanwhile, in FIG. 4, in a case of standardizing by the method disclosed in Patent Document 3, for example, the spectrum of the light emitted when the output power of the infrared light lamp 104 is 70% is acquired in advance, the spectrum of the acquired light is used in common, and the spectrum obtained from the photodetector 109 for each output power is standardized. Comparing FIG. 3 and FIG. 4, in the method disclosed in Patent Document 3, the spectrum of the light emitted from the infrared light lamp 104 set to a certain output power value is used to standardize the spectrum obtained at the photodetector 109, so that it can be seen that when the output power of the infrared light lamp 104, that is, the intensity of the emitted light is different, the shape of the standardized spectrum is also greatly different.

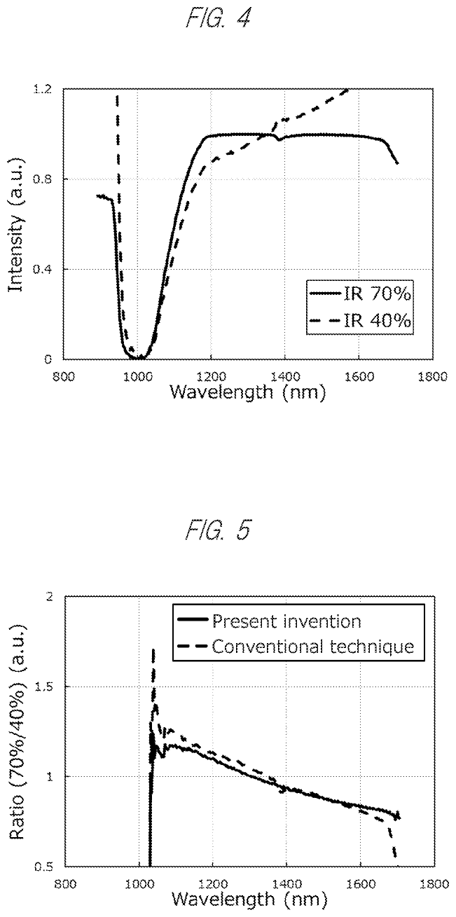

FIG. 5 is a graph showing one example of a result of comparing the standardized spectrum shown in FIG. 3 and the standardized spectrum shown in FIG. 4. FIG. 5 shows: in the spectrum shown in FIG. 3, a value obtained by dividing the light intensity for each wavelength when the output power of the infrared light lamp is 70% by the light intensity for each wavelength when it is 40%; and in the spectrum shown in FIG. 4, a value obtained by the same calculation. Here, it is confirmed that the temperature of the wafer 103 is 60° C. by bringing a thermocouple into contact with the wafer 103 even when the output power of the infrared light lamp 104 is any of 70% and 40%.

As shown in FIG. 5, the standardization by the method of the first embodiment indicated by a solid line is compared with the standardization by the method disclosed in Patent Document 3 indicated by a broken line, and it can be seen that when the output powers the infrared light lamp 104 are different, a difference between the standardized spectra (second spectra) obtained at the respective output powers can be significantly reduced. That is, even if the intensity of the light emitted from the infrared light lamp 104 is different, the standardization by the method of the first embodiment makes it possible to obtain the standardized spectrum having a closer shape correspondingly to a certain temperature, herein 60° C. As a result, the temperature of the wafer 103 detected based on the standardized spectrum can also be obtained with high accuracy regardless of the intensity of the radiated light.

### Regarding Bandedge Determination Processing

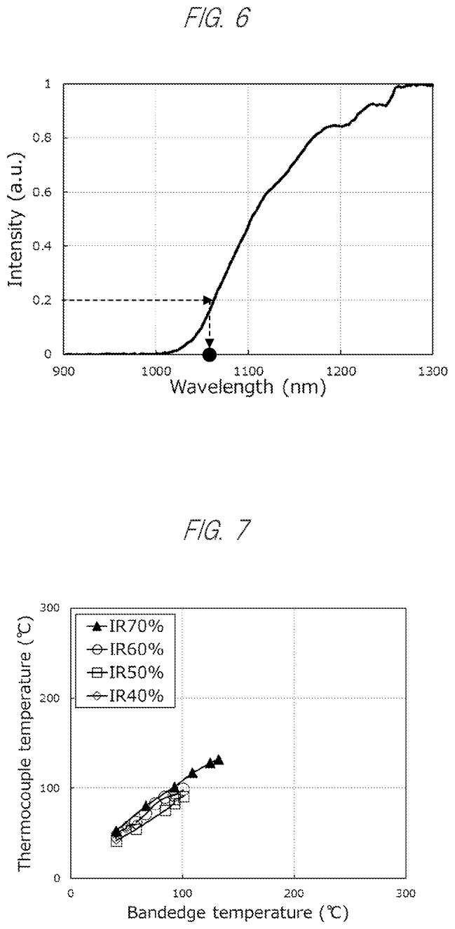

FIG. 6 is a graph showing a part of the standardized spectrum shown in FIG. 3, and is a graph explaining one example of a method of specifying a bandedge wavelength. FIG. 6 shows a wavelength range of 900 to 1300 nm extracted from the standardized spectrum when the output power of the infrared light lamp 104 is 70% in FIG. 3. A parameter on a vertical axis is an intensity as standardized spectrum magnitude, and is represented by a value within a range of 0 to 1.0. In the standardized spectrum, the controller 110 determines, as a bandedge wavelength, such a wavelength that the spectral intensity is a specific intensity, in this example has an intensity of 0.2 in a range from the local minimum wavelength to the local maximum wavelength, that is, in a range of 1060 to 1230 nm, the range from the local minimum wavelength to the local maximum wavelength reflecting the above-mentioned absorption edge.

Regarding a method of determining this specific intensity, the wafer 103 used in the first embodiment has a circular basic material made of silicon (Si), and since the silicon has an indirect transition type bandgap, a short wavelength region reflects absorption due to phonon to make a rising of the spectrum sluggish. Therefore, in order to avoid such an influence of phonon absorption, the controller 110 performs a boundary condition processing. In the boundary condition processing, the controller 110 first differentiates the standardized spectrum with respect to the wavelength to calculate an inflection point at which a first-order differentiated value is the maximum, and determine the specific intensity based on a spectrum intensity at the above-mentioned inflection point.

Specifically, it is desirable that the specific intensity is a value greater than or equal to the spectral intensity at the inflection point in order to avoid the influence of the phonon absorption, that is, a value for determining the bandedge wavelength from the region excluding the short wavelength region is desirable. In other words, it is desirable that the bandedge wavelength is set to a wavelength having a specific intensity in a longer wavelength range including the wavelength at the inflection point. Meanwhile, if the specific intensity becomes too large beyond the inflection point, a change in spectral intensity with respect to temperature change may become small. Here, in the assumed temperature measurement range of the wafer 103, the standardized spectrum has the inflection point within an intensity range of 0.15 to 0.2. For this reason, in the example of FIG. 6, 0.2, which is the highest intensity in the range of inflection points, is set as the specific intensity.

### Regarding Temperature Calculation Processing

In the first embodiment, prior to actually manufacturing the semiconductor device, correlation data between the temperature and the bandedge wavelength value in the wafer 103, for example, a calibration formula is obtained. Specifically, for example, a wafer 103 having the same or an equivalent configuration as or to the wafer 103 to be processed is prepared. Then, while maintaining the wafer 103 within a predetermined temperature range by using a temperature controller such as a hot plate, an infrared light source having a predetermined light intensity is used to calculate the correlation data between the temperature of the wafer 103 and the value of the bandedge wavelength, for example, a calibration formula.

Thereafter, in actually manufacturing the semiconductor device, a spectrum of transmitted light from the wafer 103 to be processed is measured by the photodetector 109 shown in FIG. 1B. The controller 110 performs the standardization processing as described in FIG. 3 on the measured spectrum, and then identifies the bandedge wavelength for the standardized spectrum by the method described with reference to FIG. 6. At this time, a specific intensity for specifying the bandedge wavelength, for example, 0.2 is fixed in advance. The controller 110 then compares the specified bandedge wavelength with the correlation data, converts the bandedge wavelength into temperature, and executes a temperature calculation processing for detecting the temperature of the wafer 103.

Incidentally, details regarding the calculation of the correlation data between the temperature of the wafer 103 and the value of the bandedge wavelength by using the hot plate described above will be described later in a third embodiment. Further, the correlation data described above can be commonly used regardless of the output power of the infrared light lamp 104 and eventually the intensity of the irradiated light as long as the type of the wafer 103, for example, the substrate resistance value is the same. Furthermore, the correlation data described above can be used in common regardless of the type of wafer 103 although the details will be described later. However, depending on the required temperature detection accuracy, a plurality of pieces of correlation data corresponding to the type of wafer 103 may be prepared.

### Verification Result of Temperature Detection Method by First Embodiment

FIG. 7 is a graph showing one example of comparing temperature of a semiconductor wafer detected by using the method of the first embodiment and temperature of a semiconductor device detected by a contact thermocouple when output power or input power of an infrared light lamp is varied between 40% and 70% in the etching apparatus shown in FIG. 1B. 3. When the contact thermocouple is used, temperature inside the wafer 103 is detected by attaching a thermocouple with cement to an inside of a notch formed in a silicon wafer 103.

As shown in FIG. 7, the temperature detected by using the method of the first embodiment and the temperature detected by using the thermocouple fall within a small range to such a degree that both are considered as the same temperature even when the light intensity conditions from the infrared light lamp 104 are different. As described above, by using the method of the first embodiment, it is possible to detect the temperature of the wafer 103 with high accuracy regardless of the light intensity from the infrared light lamp 104.

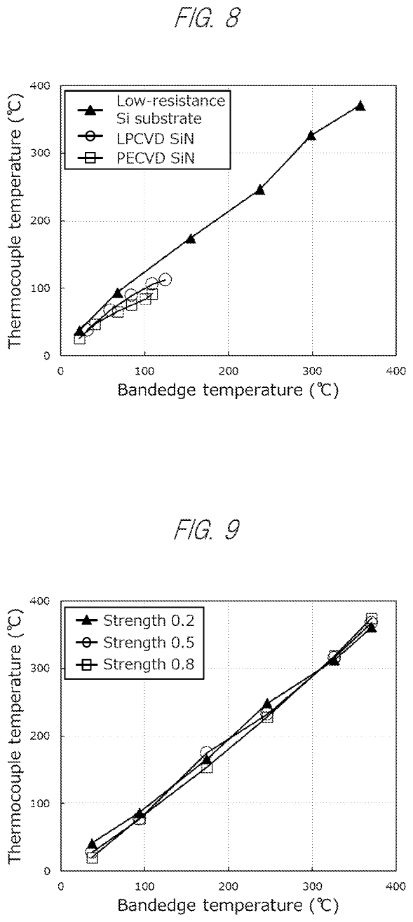

FIG. 8 is a graph showing one example of comparing the temperature of the semiconductor wafer detected by the method of the first embodiment and the temperature of the semiconductor wafer detected by using the thermocouple for different types of semiconductor wafers. In an example shown in FIG. 8, used as the wafer 103 have been a low resistance wafer having a resistivity of 0.019 Ωcm, a wafer obtained by depositing a SiN film having a thickness of 400 nm on the low resistance wafer by a LPCVD method, and a wafer obtained by depositing a SiN film having a film thickness of 100 nm formed on the low resistance wafer by a PECVD method. Further, for these wafers 103, the bandedge wavelength is specified by using the method of the first embodiment, and a method of converting the bandedge wavelength to the temperature based on the correlation data calculated by using the high resistance wafer, for example, a calibration formula is used.

As shown in FIG. 8, the temperature of the wafer 103 detected by using a single calibration formula and the temperature detected by using the contact thermocouple from infrared light passing through a plurality of types of wafers 103 fail within a small range to such a degree that both are considered as the same temperature. Thus, using the method of the first embodiment makes it possible to detect the temperature of the wafer 103 with high accuracy by using the single calibration formula even if the wafer 103 is of a different type.

FIG. 9 is a graph showing one example of comparing temperature of the semiconductor wafer detected by using the method of the first embodiment and temperature of the semiconductor wafer detected by using the thermocouple for targets of the low resistance wafers in the etching apparatus shown in FIG. 1B. In FIG. 9, at each plot point, a horizontal axis indicates temperature detected by using the method of the first embodiment, and a vertical axis indicates temperature detected by using the thermocouple. Specifically, first, a low resistance wafer is placed in the etching apparatus 100, and the temperature of the wafer is detected by using the method of the first embodiment so that the temperature of the wafer reaches a predetermined temperature, for example, around 40° C. At the same time, the wafer is heated while feedback-controlling the infrared light lamp 104 based on a detection result.

During the feedback control, the spectrum of the light transmitted through the wafer is sequentially measured by the photodetector 109, and the measured spectrum is targeted and is standardized by the method described in FIG. 3. Also, for the standardized spectrum as a target, as described in FIG. 6, for example, the bandedge wavelength is specified by setting the specific intensity to 0.2, and the bandedge wavelength is converted to temperature by using a single calibration formula. Then, target temperature of the feedback control at the time when such feedback control converges is plotted by a black triangle near 40° C. on the horizontal axis of FIG. 9. Also, at the time when the feedback control converges, the value obtained by detecting the temperature of the wafer by using the thermocouple is indicated by the value on the vertical axis in FIG. 9.

Then, results after such an operation is performed based on setting the values of the specific intensity described in FIG. 6 as 0.5 and 0.8 become plots of circle marks and plots of square marks, respectively. Furthermore, by performing the same operation while changing the value of the specific intensity and changing the target temperature of the feedback control, a graph as shown in FIG. 9 is obtained. As shown in FIG. 9, it is understood that even when the target temperature and the specific intensity are changed, the value of the temperature detected by using the method of the first embodiment is within a range that can be considered to be approximately equal to the temperature detected by using the thermocouple.

### Main Effect of First Embodiment

As described above, in the first embodiment, the spectrum of the light irradiated by the heating infrared light lamp 104 and transmitted through the semiconductor wafer 103 is measured, and the spectrum is standardized by setting an appropriate wavelength range, the temperature of the wafer 103 is detected by determining the bandedge wavelength from the standardized spectrum and comparing the previously obtained correlation data between the value of the bandedge wavelength and the temperature of the wafer 103. This makes it possible to detect the temperature of the wafer 103 with high accuracy. In addition, the processing efficiency can be improved in the semiconductor processing apparatus.

Specifically, even if the conditions of the light and electromagnetic waves with which the wafer 103 is irradiated, the type of the wafer 103, and the type and structure of the film formed on the wafer 103 change, the temperature can be stably, in other words, robustly detected. In addition, even if analysis parameters in determining the bandedge wavelength are changed, the temperature can be detected stably to some extent. Furthermore, by using the calibration formula calculated for the single wafer 103, the temperatures of the plurality of wafers 103 of different types can be detected with high accuracy. At this time, as in the conventional technique, works or the like of: preparing a reference spectrum from the infrared light lamp 104 for each heating condition of the wafer 103; and preparing a calibration formula for each type of the wafer 103 and each heating condition of the wafer 103 become unnecessary, and the processing efficiency is enhanced.

### Second Embodiment

### Details of Temperature Detection Method

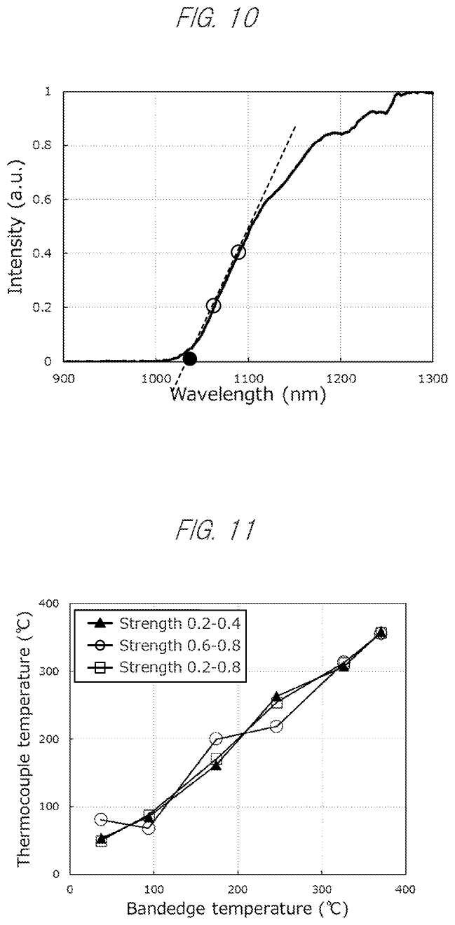

A second embodiment will be described with reference to FIGS. 10 and 11. In a second embodiment, as in the case of FIG. 1B in the first embodiment, used is an etching apparatus 100 in which a semiconductor wafer 103 placed on a wafer stage 102 can be heated by an infrared light lamp 104 arranged above a processing chamber 101. Then, the temperature of the wafer 103 is detected based on the spectrum of the light or electromagnetic wave that is irradiated by the infrared light lamp 104 and passes through the semiconductor wafer 103.

Specifically, also in the second embodiment, as in the first embodiment, a light receiver arranged inside the wafer stage 102 receives light or electromagnetic waves from the infrared light lamp 104 passing through the wafer 103 and divides the light or electromagnetic waves into a plurality of wavelengths by the spectroscope 108, and the photodetector 109 measures a spectrum (first spectrum) indicating a light intensity for each wavelength. Then, the controller 110 standardizes the measured spectrum, determines a bandedge wavelength from data of the standardized spectrum (second spectrum), compares the predetermined acquired correlation data between the value of the bandedge wavelength and the temperature of the wafer 103, for example, the calibration formula to detect the temperature of the wafer 103. However, the second embodiment differs from the first embodiment in a method of specifying the bandedge wavelength.

### Regarding Bandedge Determination Processing

FIG. 10 is a graph showing part of the standardized spectrum shown in FIG. 3 in the semiconductor processing apparatus according to the second embodiment, and is a graph for explaining one example of a method of specifying a bandedge wavelength. FIG. 10 shows a wavelength range of 900 to 1300 nm extracted from the standardized spectrum when the output power of the infrared light lamp 104 is 70% in FIG. 3, as in the case of FIG. 6.

As shown in FIG. 10, the controller 110 uses the standardized spectral data as a target, and selects two points with specific spectral intensities in a range of the local minimum wavelength which reflects the absorption edge described in the first embodiment, that is, in a range of a wavelength of 1060 to 1230 nm. Then, the controller 110 determines, as a bandedge wavelength, a wavelength at which the light intensity is 0 in a linear first-order characteristic passing through the selected two points, that is, a value of a wavelength at an intersection of a straight line passing through the two points and the horizontal axis.

Here, a short wavelength point of the two points is desirably selected based on a point at which a value obtained by linearly differentiating the standardized spectrum with respect to the wavelength becomes the maximum, that is, based on the inflection point as in the case of FIG. 6. Meanwhile, regarding a point on a long wavelength side out of the two points, in the second embodiment, the maximum value which the temperature of the wafer 103 reaches is around 500° C., and a bandgap of silicon (Si) at 500° C. is 1.01 eV, this corresponding to 1230 nm which is the local maximum wavelength. In bandgaps, bandedges widen due to thermal energy as temperature rises. Consequently, by using as the maximum wavelength (second maximum wavelength) 1150 nm which is a wavelength corresponding to 1.08 eV totaling the value of the bandgap and a thermal energy value of 0.07 eV at 500° C., the point on a long wavelength side is determined as the maximum wavelength, or is preferably selected in a range of the shorter wavelength than the maximum wavelength.

### Verification Result of Temperature Detection Method by Second Embodiment

FIG. 11 is a graph showing one example comparing the wafer temperature obtained from the bandedge wavelength specified by the method shown in FIG. 10 and the wafer temperature obtained by using a thermocouple. Here, two values is selected from three values that are spectral intensity values in a range of 0.2 to 0.8 and, for each set selected, the temperature of the wafer 103 is detected based on the bandedge wavelength specified by the method shown in FIG. 10 and the temperature is detected also by the output from the thermocouple brought into contact with the wafer 103. An example of FIG. 11 shows temperatures detected by these two methods.

As shown in FIG. 11, in using a set in which spectral intensities are 0.2 and 0.4, temperature approximately equal to the temperature of the wafer 103 obtained by using the thermocouple is obtained. Meanwhile, in using a set of points where spectral intensities are 0.6 and 0.8, the temperature values corresponding to the bandedge wavelength are greatly variable. This is because a degree of light absorption differs depending on a material forming an optical path inside the wafer stage 102 through which the light transmitted through the wafer 103 passes, and a degree of light absorption also differs depending on free carriers of the wafer 103 (low-resistance wafer). As a result, it is considered that the linearity of the normalized spectrum is broken.

Non-Patent Document 1 discloses a method of specifying a bandedge by using a tangent to the spectrum of transmitted light, but in using a tangent defined in a narrow wavelength range as described above, there is a wavelength range in which it is difficult to stably detect the temperature of the semiconductor wafer 103. FIG. 11 also shows the temperature of the wafer 103 detected in using a set of spectral intensities of 0.2 and 0.8. Also in using a set of points where spectral intensities are 0.2 and 0.8, obtained have been temperatures approximately equal to those of the wafer 103 obtained by using the thermocouple.

From the above, it can be seen that: in using the set of spectral intensities of 0.2 and 0.8, the difference with the temperature detected by using the thermocouple becomes sufficiently small regardless of a long wavelength range which it has been difficult to stably detect in using a narrow wavelength range, that is, a range including the set of 0.6 and 0.8; and the temperature values that agree to each other to such an extent that both can be regarded as approximately equal can be obtained. By such a result, as in the second embodiment, when a range of part of the standardized spectrum is approximated with a first-order straight line and the bandedge wavelength is specified based on the straight line, definition of the straight line approximated within the widest possible range is preferably for the stable temperature detection.

Meanwhile, in a range of wavelengths significantly deviated from the absorption edge, a change in shapes of the spectrum of light due to temperature becomes small, so that it is difficult to stably detect the temperature of the wafer 103. Therefore, as shown in the second embodiment, it is preferable to select such two points as to include a point corresponding to the sum of the bandgap and the thermal energy at the highest temperature assumed as a temperature measurement range of the wafer 103, i.e., a point corresponding to 1150 nm which is the maximum wavelength, alternatively, include as one point a point where the spectral intensity is 0.8. Also, the other one of the two points is preferably determined based on the inflection point described in FIG. 6, for example, the point where the spectral intensity is 0.2. Then, it is preferable to specify the bandedge wavelength based on the line passing through the two points.

### Third Embodiment

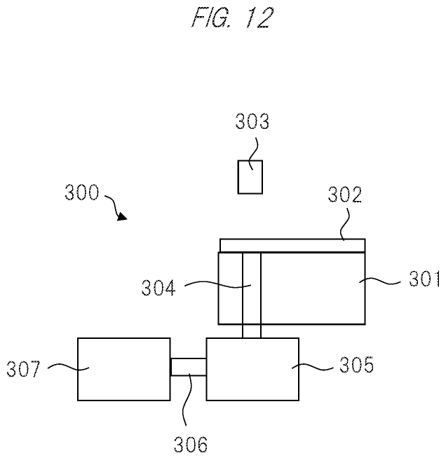

Next, a third embodiment will be described with reference to FIGS. 12 to 14. In a third embodiment, instead of the infrared lamp 104 of the etching apparatus 100 described in the first embodiment, a hot plate, which is a heater for heating the semiconductor wafer, is arranged inside the wafer stage. By using such a wafer stage, the temperature of the wafer can be detected even when the bandedge wavelength is specified from the spectrum of light or electromagnetic waves transmitted through the wafer placed on the wafer stage.

### Schematic Configuration of Semiconductor Processing Apparatus

FIG. 12 is a sectional view showing a schematic configuration example of a semiconductor processing apparatus according to a third embodiment. A semiconductor processing apparatus shown in FIG. 12, more specifically, a heating apparatus 300 has a wafer stage 301, an infrared light source 303, an optical path 304, a spectroscope 305, a photodetector 306, and a controller 307. The wafer stage 301 has, for example, a cylindrical shape, and mounts on its circular upper surface a semiconductor wafer 302 which is an object to be detected of temperature. The infrared light source 303 is arranged above the wafer stage 301 and irradiates the wafer 302 with light or electromagnetic waves.

The optical path 304 has an optical fiber attached inside the wafer stage 301. The spectroscope 305 is connected to the optical path 304 and disperses light that is received by a light receiving unit having a translucent member and attached to a tip of the optical fiber. The photodetector 306 measures an intensity of the light dispersed by the spectroscope 305. The controller 307 identifies the bandedge wavelength by numerically processing the spectrum (first spectrum) obtained by the photodetector 306, and detects the temperature of the wafer 302 from the bandedge wavelength.

FIG. 12 shows a configuration of using the wafer stage 301 incorporating the hot plate including a heater to heat the wafer 302 placed on its upper surface. However, it goes without saying that an effect of a heating configuration is the same even if the heater is not used. Further, FIG. 12 shows a configuration of measuring the spectrum from light or electromagnetic waves that is emitted from the infrared light source 303 arranged above the upper surface side of the wafer 302 and is transmitted through the wafer 302. However, adopted may be a configuration of: arranging an infrared light source inside the wafer stage 301 on the back side of the wafer 302; and measuring a scattering reflection spectrum obtained by being emitted on the back side of the wafer 302.

### Details of Temperature Detection Method

### Regarding Bandedge Determination Processing

FIG. 13 is a graph showing one example of a standardized spectral distribution obtained from the heating apparatus shown in FIG. 12. For the standardization, a method similar to the method described with reference to FIG. 3 in the first embodiment is used. That is, the controller 307 standardizes the spectrum obtained by the photodetector 306 by the method described with reference to FIG. 3, thereby obtaining a standardized spectrum (second spectrum) as shown in FIG. 13. However, the third embodiment differs from the first embodiment and the second embodiment in the method of specifying the bandedge wavelength from the standardized spectrum.

That is, in the third embodiment, as shown in FIG. 13, the controller 307 performs integration with a wavelength according to a quadrature mensuration by parts, for the standardized spectrum, in the range from the local minimum wavelength to the local maximum wavelength which reflects the absorption edge described above, that is, in the range of 1060 to 1230 nm, thereby calculating an area of a portion of the range on the graph and setting it as the maximum area. Further, the controller 307 sets as a reference area a value obtained by multiplying the reference area by a coefficient K that satisfies 0<K<1. Then, the controller 307 determines the wavelength at which the integrated value from the local minimum wavelength becomes the reference area as the bandedge wavelength. In an example of FIG. 13, a value of ½ is used as the coefficient K.

In the third embodiment, a specific structure composed of a single or multiple layers of film is formed on the wafer 302 made of silicon (Si), and an interference pattern derived from the structure on the wafer 302 can occur. In particular, when such an interference pattern occurs, it is possible to cancel an effect of oscillation of a spectral intensity due to the interference by using the integration method as described above.

Incidentally, the reference area may be fixed in advance, for example, through experiments. In this case, every time the temperature of the wafer 302 is actually measured, a spectrum (first spectrum) obtained by the photodetector 306 is integrated by setting 1060 nm as a starting point, and the wavelength when the integrated value reaches the reference area may be specified as the bandedge wavelength. Alternatively, each time the temperature of the wafer 302 is actually measured, the maximum area is calculated for the spectrum obtained by the photodetector 306 and the reference area is calculated from the maximum area and the bandedge wavelength may be specified from the reference area.

### Verification Result of Temperature Detection Method by Third Embodiment

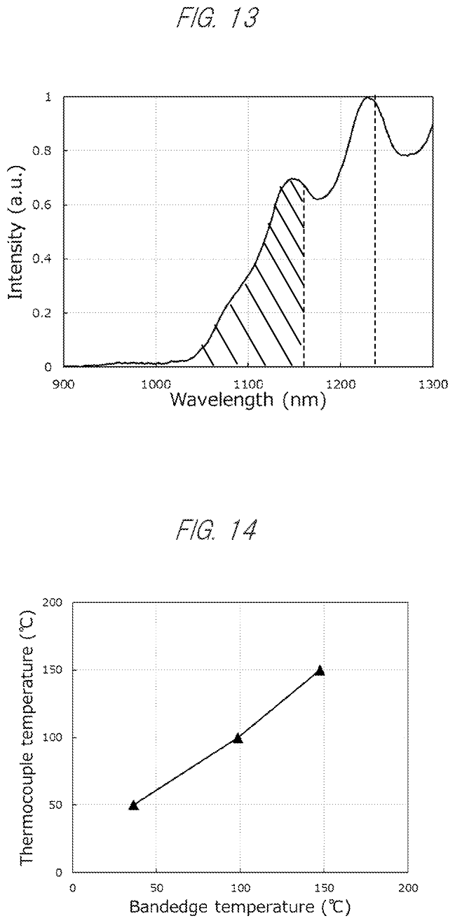

FIG. 14 is a graph showing one example that compares the temperature of the wafer and the temperature of the hot plate obtained by setting a wavelength having an integrated value of 0.55 times the maximum area as a bandedge wavelength in the heating apparatus shown in FIG. 12. Specifically, a spectrum of the light emitted from the infrared light source 303 and transmitted through the silicon wafer 302 having a specific structure on its surface is standardized, and a bandedge wavelength is specified. FIG. 14 shows a value of temperature detected by comparing the specified bandedge wavelength and the calibration formula and a value of temperature detected by using an output from a temperature sensor such as a thermocouple connected to the hot plate at that time.

Here, in the third embodiment, the temperature of the wafer 302 is detected after a sufficient amount of time has passed after the hot plate is heated, and the thermal conductivity of the wafer 302 made of single crystal silicon is very high. Therefore, it is considered that the temperature of the hot plate and the temperature of the wafer 302 are almost equal. As shown in FIG. 14, it can be seen that the temperature of the wafer 302 obtained from the bandedge wavelength specified by using the integration method is approximately equal to the temperature of the hotplate, and the temperature of the wafer 302 can be measured with sufficient accuracy in a non-contact manner.

Incidentally, the bandedge wavelength determination method by using the integration method according to the third embodiment may be applicable not only to the heating apparatus 300 shown in FIG. 12 but also to the etching apparatus 100 shown in FIG. 1B. Moreover, the heating apparatus 300 shown in FIG. 12 may be used in preparing in advance the correlation data between the values of the temperature and the bandedge wavelength described in the first embodiment, for example, the calibration formula. That is, using the heating apparatus 300 as shown in FIG. 12 makes it possible to create a highly accurate calibration formula with a simple configuration and a simple method based on the temperature sensor such as the thermocouple connected to the hot plate.

### Fourth Embodiment

### Details of Temperature Detection Method

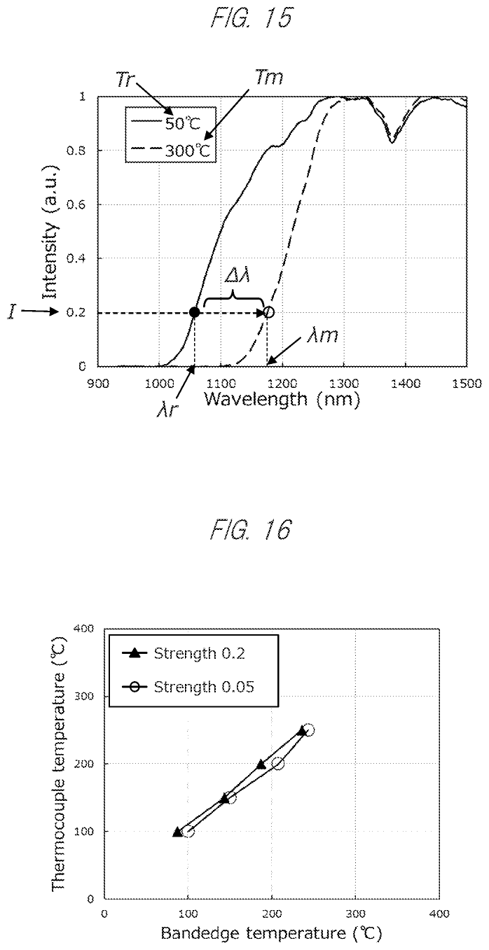

A fourth embodiment will be described with reference to FIGS. 15 and 16. In a fourth embodiment, as in the case of FIG. 12 in the third embodiment, used is a configuration of measuring a spectrum from light or electromagnetic waves emitted from the infrared light source 303 arranged above the upper surface side of the wafer 302 and transmitted through the wafer 302.

### Regarding Bandedge Determination Processing

FIG. 15 is a graph showing one example of a standardized spectral distribution obtained from the heating apparatus shown in FIG. 12. For the standardization, a method similar to the method described with reference to FIG. 3 in the first embodiment is used. That is, the controller 307 standardizes the spectrum obtained by the photodetector 306 by the method described with reference to FIG. 3, thereby obtaining a standardized spectrum (second spectrum) as shown in FIG. 15. However, the fourth embodiment differs from the first and second embodiments, and Example 3 in a method of specifying the bandedge wavelength from the standardized spectrum.

That is, in the fourth embodiment, as shown in FIG. 15, the controller 307 calculates a reference wavelength λr having a specific intensity I in the standardized spectrum at reference temperature Tr and a measurement wavelength λm having a specific intensity I in the standardized spectrum at arbitrary measurement temperature Tm to be measured, and determines a wavelength difference Δλ between the reference wavelength λr and the measurement wavelength λm as a bandedge wavelength. The reference temperature Tr is desirably temperature in a steady state, but may be set to arbitrary temperature in accordance with the heating apparatus. In an example of FIG. 15, 50° C. is used as the reference temperature Tr. The specific intensity I is desirably a value close to 0 at which interference of transmitted light by the wafer 302 and a film on the wafer 302 is less likely to occur. In the fourth embodiment, 0.2 or 0.05 is used as the specific intensity I.

In the fourth embodiment, the used silicon (Si) wafer 302 has a resistivity of 0.005 Ωcm (hereinafter referred to as an ultra-low resistance wafer). In particular, for such ultra-low resistance wafers, absorption of light by the wafer is greater than that of high resistance wafers, and a shape of the spectrum can be significantly different. Therefore, using the finite difference method as described above makes it possible to cancel changes in the shapes of the spectrum. That is, there may be deviations in the reference wavelength λr and the measurement wavelength λm between one ultra-low resistance wafer and another ultra-low resistance wafer, but the wavelength difference Δλ is considered to be constant. Therefore, for each wafer 302, first, the reference wavelength λr is calculated in a steady state, then the measurement wavelength λm and the wavelength difference Δλ are calculated while increasing the temperature, and the wavelength difference Δλ is converted into temperature based on a previously prepared calibration formula, thereby being able to detect the measurement temperature Tm of the wafer 302.

### Verification Result of Temperature Detection Method by Fourth Embodiment

FIG. 16 is a graph showing one example comparing the temperature of the wafer and the temperature of the hot plate obtained by determining the bandedge wavelength from a wavelength difference between the reference wavelength at the reference temperature and the measurement wavelength at the measurement temperature in the heating apparatus shown in FIG. 12. In an example of FIG. 16, 50° C. is used as reference temperature, and 0.2 and 0.05 are used as specific intensities I in calculating the reference wavelength λr and the measurement wavelength λm.

Specifically, a spectrum of the light emitted from the infrared light source 303 and transmitted through the silicon wafer 302 having a specific structure on its surface is standardized, and a bandedge wavelength is specified from the standardized spectrum by the method shown in FIG. 15. FIG. 16 shows a temperature value detected by comparing the specified bandedge wavelength and a calibration formula formulated by using the spectrum of the high resistance wafer by the method shown in FIG. 15, and a temperature value detected by using the output from the temperature sensor such as the thermocouple connected to the hot plate.

Here, in the fourth embodiment, the temperature of the wafer 302 is detected after a sufficient amount of time has elapsed after the hot plate is heated, and the thermal conductivity of the single-crystal silicon wafer 302 is very high. Therefore, it is considered that the temperature of the hot plate and the temperature of the wafer 302 are almost equal. As shown in FIG. 16, the temperature of the wafer 302 obtained from the bandedge wavelength specified based on the wavelength difference Δλ between the reference wavelength λr and the measurement wavelength λm is approximately equal the temperature of the hot plate, so that it can be seen that the temperature of the ultra-low resistance wafer can be measured with sufficient accuracy by a non-contact method even when the calibration formula calculated by using the high resistance wafer is used. Even when the specific intensity I is 0.2, the temperature can be measured with accuracy in a range of 20° C. or lower, but when the specific intensity I is 0.05, the temperature can be measured with accuracy in a range of 10° C. or lower. Consequently, it is desirable that the specific intensity I is small enough to be unaffected by noise in a signal.

Incidentally, the bandedge wavelength determination method using the difference method according to the fourth embodiment is applicable not only to the heating apparatus 300 as shown in FIG. 12 but also to the etching apparatus 100 as shown in FIG. 1B. Moreover, the heating apparatus 300 shown in FIG. 12 may be used in preparing in advance the correlation data between the temperature and the bandedge wavelength value described in the fourth embodiment, for example, the calibration formula. That is, using the heating apparatus 300 as shown in FIG. 12 makes it possible to create a highly accurate calibration formula with a simple configuration and a simple method based on the temperature sensor such as the thermocouple connected to the hot plate.

### Fifth Embodiment

### Details of Temperature Detection Method

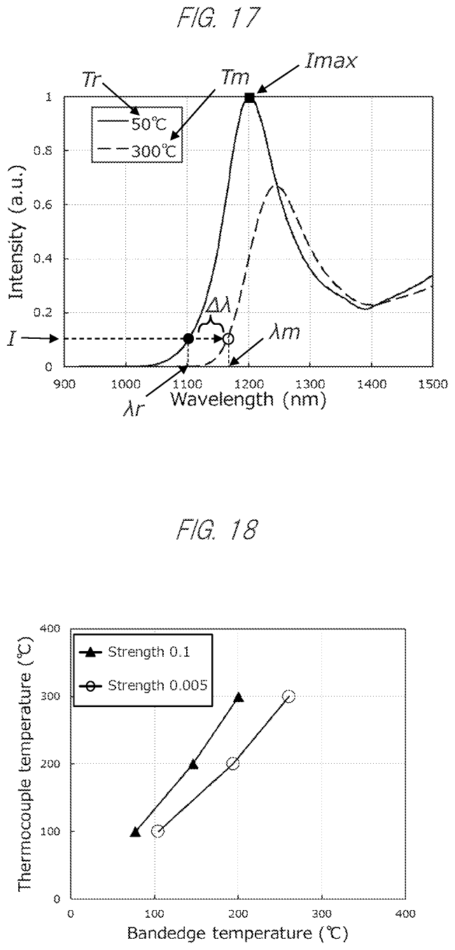

A fifth embodiment will be described with reference to FIGS. 17 and 18. In a fifth embodiment, as in the case of FIG. 12 in the third embodiment, a spectrum is measured from light or electromagnetic waves emitted from the infrared light source 303 arranged above the upper surface side of the wafer 302 and transmitted through the wafer 302.

### Regarding Standardization Processing

FIG. 17 is a graph showing one example of a standardized spectral distribution obtained from the heating apparatus shown in FIG. 12. For normalization, a method slightly different from the method described in FIG. 3 in the first embodiment is used and, instead of determining the maximum value for each spectrum as in the case of FIG. 3, the maximum value is determined at a spectrum that becomes a reference.

That is, in the fifth embodiment, the controller 307 calculates the maximum value of the light intensity from the first spectrum at the reference temperature Tr, determines the local minimum value of the light intensity from the measured first spectrum for each arbitrary measurement temperature Tm to be measured, and determines as the local maximum value a value obtained by taking a difference between the maximum value at the reference temperature Tr and the determined local minimum value for each measurement temperature Tm. Then, the controller 307 performs a difference processing with the local minimum value determined at the measured temperature Tm with respect to the first spectrum at the measured temperature Tm and, thereafter, divides it by the local maximum value determined by using the common maximum value at the measured temperature Tm, thereby standardizing the first spectrum. With such standardization, as shown in FIG. 17, the second spectrum at the reference temperature Tr is standardized so that the local minimum value is 0 and the local maximum value Imax is 1.0. meanwhile, in the second spectrum at the measurement temperature Tm, the local minimum value is 0, but the local maximum value is not always 1.0.

### Regarding Bandedge Determination Processing

After performing the standardization processing as described above, the controller 307 performs a bandedge determination processing to e standardized second spectrum by using the finite difference method described in the fourth embodiment. That is, as shown in FIG. 17, the controller 307 calculates a reference wavelength λr with a specific intensity I in the second spectrum at the reference temperature Tr and a measurement wavelength λm with a specific intensity I in the second spectrum at the measurement temperature Tm, and determines, as a bandedge wavelength, a wavelength difference Δλ between the reference wavelength λr and the measurement wavelength λm. Then, the controller 307 converts the wavelength difference Δλ into temperature based on a calibration formula prepared in advance. The reference temperature Tr is desirably temperature in a steady state, but may be set to arbitrary temperature in accordance with the heating apparatus. In the fifth embodiment, 50° C. is used as the reference temperature Tr, and 0.1 or 0.005 is used as the specific intensity I.

In the fifth embodiment, a 100 nm-thickness SiO film and a 500 nm-thickness polycrystalline Si film are formed on a silicon (Si) wafer 302, and an interference pattern derived from a structure on the wafer 302 can occur. In particular, when such an interference pattern occurs, using the standardization method and fine difference method as described above make it possible to cancel the effect of oscillation of the spectral intensity due to the interference. As shown in FIG. 17, when the interference pattern derived from the structure on the wafer 302 changes its local maximum value, the specific intensity I has desirably a value nearby 0 as to be less susceptible to the interference of the transmitted light due to the wafer 302 and the film on the wafer 302.

### Verification Result of Temperature Determination Method by Fifth Embodiment

FIG. 18 is a graph showing one example of comparing the temperature of the wafer and the temperature of the hot plate, which have been obtained by determining the bandedge wavelength from the wavelength difference between the reference wavelength at the reference temperature and the measurement wavelength at the measurement temperature after standardizing by using the local maximum value of the first spectrum at the reference temperature. In the example of FIG. 18, 50° C. is used as the reference temperature, and 0.1 and 0.005 are used as the specific intensity I in calculating the reference wavelength λr and the measurement wavelength λm.

Specifically, the spectrum of the light emitted from the infrared light source 303 and transmitted through the silicon wafer 302 having a specific structure on the surface is standardized by the method shown in FIG. 17, and the bandedge wavelength is specified from the standardized spectrum by the method shown in FIG. 17. FIG. 18 shows: the temperature value detected by comparing the specified bandedge wavelength with the calibration formula formulated by using the spectrum of the high resistance wafer thought the method shown in FIG. 17; and the temperature values detected by using the output from a temperature sensor such as a thermocouple connected to the hot plate in being compared and detected.

Here, in the fifth embodiment, the temperature of the wafer 302 is detected after a sufficient amount of time has elapsed after the hot plate is heated, and the thermal conductivity of the single crystal silicon wafer 302 is very high, so that it is considered that the temperature of the hot plate and the temperature of the wafer 302 are almost equal. As shown in FIG. 18, it can be seen that the temperature of the wafer 302 obtained from the bandedge wavelength specified based on the wavelength difference Δλ between the reference wavelength λr and the measurement wavelength λm is approximately equal to the temperature of the hot plate and can be measured with sufficiently accurate by the non-contact method. When the specific intensity I is 0.1, the accuracy of temperature measurement is poor, but when the specific intensity I is 0.005, the temperature can be measured with accuracy within 35° C. Consequently, it is desirable that the specific intensity I is small enough to be unaffected by noise in the signal.

Incidentally, the bandedge wavelength determination method using the fine difference method according to the fifth embodiment is applicable not only to the heating apparatus 300 as shown in FIG. 12 but also to the etching apparatus 100 as shown in FIG. 1B. Moreover, the heating apparatus 300 shown in FIG. 12 may be used in preparing in advance the correlation data between the temperature and the bandedge wavelength value described in the fifth embodiment, for example, the calibration formula. That is, using the heating apparatus 300 as shown in FIG. 12 makes it possible to create the highly-accurate calibration formula with a simple configuration and a simple method based on a temperature sensor such as a thermocouple connected to the hot plate.

Although the invention made by the inventor(s) has been specifically described above based on the embodiments, the invention is not limited to the embodiments and can be variously modified without departing from the gist of the invention. For example, the embodiments described above have been described in detail in order to explain the present invention in an easy-to-understand manner, and are not necessarily limited to those having all the configurations described. Also, part of the configuration of one embodiment can be replaced with the configuration of another embodiment, and the configuration of another embodiment can be added to the configuration of one embodiment. Moreover, it is possible to add, delete, or replace a part of the configuration of each embodiment to, from, or with another configuration.

### EXPLANATION OF REFERENCE NUMERALS

100 . . . Etching apparatus; 101 . . . Processing chamber; 102 . . . Wafer stage; 103 . . . Semiconductor wafer; 104, 104-1 to 104-3; Infrared light lamp; 105 . . . Plasma source (Discharge chamber); 106 . . . Plate member; 107 . . . Optical path; 108 . . . Spectroscope; 109 . . . Photodetector; 110 . . . Controller; 111 . . . Base chamber; 112 . . . Quartz chamber; 113 . . . Plasma; 114 . . . Pressure regulating valve; 115 . . . Exhaust pump; 116 . . . Vacuum exhaust pipe; 117 . . . Gas dispersion plate; 118 . . . Top plate; 119 . . . Shower plate; 120 . . . High frequency power source; 122 . . . Matching box; 125 . . . Cut filter; 130 . . . Electrode plate; 131 . . . DC power source; 134 . . . ICP coil; 138 . . . Chiller; 139 . . . Flow path; 150 . . . Mass flow controller unit; 151 . . . Gas distributor; 163 . . . Reflector; 164 . . . Infrared light lamp power source; 170 . . . Thermocouple; 171 . . . Thermocouple thermometer; 174 . . . Infrared light transmission window; 175 . . . Flow path; 185 . . . Quartz rods; 191 . . . Though-hole; 192 . . . Optical fiber; 198 . . . Optical multiplexer; 300 . . . Heating apparatus; 301 . . . Wafer stage; 302 . . . Semiconductor wafer; 303 . . . Infrared light source; 304 . . . Optical path; 305 . . . Spectroscope; 306 . . . Photodetector; and 307 . . . Controller.

1. A temperature detector comprising:
a light source irradiating a semiconductor wafer with light;
a spectroscope that disperses transmitted light or scattered reflection light generated from the semiconductor wafer according to irradiation of the light;
a photodetector that measures the light dispersed by the spectroscope; and
a controller that determines a bandedge wavelength by numerically processing a first spectrum obtained by the photodetector and detects temperature of the semiconductor wafer from the bandedge wavelength,
wherein the controller performs:
a standardization processing that performs standardization by using as a local minimum wavelength a wavelength corresponding to bandgap energy of a semiconductor at absolute zero to set as a local minimum value the minimum value of a light intensity in a wavelength region shorter the local minimum wavelength and by using as a first maximum wavelength a wavelength corresponding to a difference between bandgap energy and thermal energy of the semiconductor at the highest temperature assumed as a temperature measurement range to set as a local maximum value a value obtained by taking a difference with the local minimum value from the maximum value of a light intensity in a wavelength range shorter than the first maximum wavelength to perform a difference processing with the local minimum value with the respect to the first spectrum and then divide it by the local maximum value;
a bandedge determination processing that determines the bandedge wavelength based on a second spectrum obtained in the standardization processing; and
a temperature calculation processing that detects temperature of the semiconductor wafer by comparing preliminarily acquired correlation data between values of temperature and a bandedge wavelength with the bandedge wavelength determined by the bandedge determination processing.

2. The temperature detector according to claim 1,
wherein, in the bandedge determination processing, the controller sets a wavelength having a specific intensity on the second spectrum as the bandedge wavelength.

3. The temperature detector according to claim 2,
wherein the controller uses as a local maximum wavelength a wavelength corresponding to the bandgap energy of the semiconductor at the highest temperature, and sets the specific intensity from among spectral intensities corresponding to a wavelength region from the local minimum wavelength to the local maximum wavelength.

4. The temperature detector according to claim 3,
wherein the controller first differentiates the second spectrum with respect to a wavelength to calculate an inflection point at which a first differentiated value becomes maximum, and sets the spectral intensity so as to have a value equal to or more than a spectrum strength at the inflection point.

5. The temperature detector according to claim 1,
wherein, in the-bandedge determination processing, the controller determines on the bandedge wavelength an intercept of a line passing through two points on the second spectrum and a wavelength axis, and uses as a second maximum wavelength a wavelength corresponding to a sum of the bandgap energy and the thermal energy of the semiconductor at the highest temperature to set one of the two points on the second spectrum as the second maximum wavelength.

6. The temperature detector according to claim 5,
wherein the controller first differentiates the second spectrum with respect to a wavelength, calculates the inflection point at which the first differentiated value is maximum, and determines the other of the two points on the second spectrum based on the inflection point.

7. The temperature detector according to claim 5,
wherein the controller uses as a local maximum wavelength a wavelength corresponding to the bandgap energy of the semiconductor at the highest temperature, calculates as a reference area in the bandedge determination processing a value obtained by multiplying a coefficient K (0<K<1) by integral values from the local minimum wavelength to the local maximum wavelength on the second spectrum, and sets as the bandedge wavelength such a wavelength that the integrated value from the local minimum wavelength becomes the reference area.

8. The temperature detector according to claim 1,
wherein the controller sets as the bandedge wavelength in the bandedge determination processing a wavelength difference between a reference wavelength having a specific intensity on the second spectrum at predetermined reference temperature and a measurement wavelength having the specific intensity on the second spectrum at measurement temperature is defined.

9. The temperature detector according to claim 1,
wherein, in the standardization processing, the controller sets the maximum value for the first spectrum at predetermined reference temperature, sets the local minimum value for the first spectrum for each measurement temperature, sets as the local maximum value a value obtained by subtracting the local minimum value from the maximum value, and performs a difference processing with the local minimum value with respect to the first spectrum for each measurement temperature to divide it by the local maximum value, thereby standardizing the first spectrum for each measurement temperature.

10. The temperature detector according to claim 9,
wherein, in the bandedge determination processing, the controller sets as the bandedge wavelength a wavelength difference between a reference wavelength having a specific intensity on the second spectrum at the reference temperature, and a measurement wavelength having the specific intensity on the second spectrum for each measurement temperature.

11. The temperature detector according to any one of claims 1 to 10,
wherein the controller further performs a smoothing processing due to a moving average on the first spectrum before performing the standardization processing.

12. The temperature detector according to any one of claims 1 to 7,
wherein the light source is a heating light source that heats the semiconductor wafer by irradiating the semiconductor wafer with light.

13. A semiconductor processing apparatus comprising:
a processing chamber for processing a semiconductor wafer;
a wafer stage that is installed in the processing chamber and on which the semiconductor wafer to be processed is mounted;
a plasma source that forms a plasma by using a processing gas;
a plate member installed between the processing chamber and the plasma source and including a plurality of through-holes into which the processing gas is introduced;
a heating light source that is installed so as to surround an outer periphery of the plate member and heats the semiconductor wafer by irradiating the semiconductor wafer with light;
a spectroscope that disperses transmitted light or scattered reflection light generated from the semiconductor wafer according to irradiation of the light;
a photodetector that measures the light dispersed by the spectroscope; and
a controller that determines a bandedge wavelength by numerically processing a first spectrum obtained by the photodetector, and detects temperature of the semiconductor wafer from the bandedge wavelength,
wherein the controller performs:
a standardization processing that performs standardization by using as a local minimum wavelength a wavelength corresponding to bandgap energy of a semiconductor at absolute zero to set as a local minimum value the minimum value of a light intensity in a wavelength region shorter the local minimum wavelength and by using as a first maximum wavelength a wavelength corresponding to a difference between bandgap energy and thermal energy of the semiconductor at the highest temperature assumed as a temperature measurement range to set as a local maximum value a value obtained by taking a difference with the local minimum value from the maximum value of a light intensity in a wavelength range shorter than the first maximum wavelength to perform a difference processing with the local minimum value with the respect to the first spectrum and then divide it by the local maximum value;
a bandedge determination processing that determines the bandedge wavelength based on a second spectrum obtained in the standardization processing; and
a temperature calculation processing that detects temperature of the semiconductor wafer by comparing preliminarily acquired correlation data between values of temperature and a bandedge wavelength with the bandedge wavelength determined by the bandedge determination processing.

14. The semiconductor processing apparatus according to claim 13,
wherein the controller uses as a local maximum wavelength a wavelength corresponding to bandgap energy of a semiconductor at the highest temperature, sets a specific intensity from spectral intensities corresponding to a wavelength region from the local minimum wavelength to the local maximum wavelength, and sets as the bandedge wavelength in the bandedge wavelength processing a wavelength having the specific intensity on the second spectrum.

15. The semiconductor processing apparatus according to claim 14,
wherein the controller first differentiates the second spectrum with respect to a wavelength to calculate an inflection point at which a first differentiated value becomes maximum, and sets the spectral intensity so as to have a value equal to or more than a spectrum strength at the inflection point.

16. The semiconductor processing apparatus according to claim 13,
wherein, in the-bandedge determination processing, the controller sets on the bandedge wavelength an intercept of a line passing through two points on the second spectrum and a wavelength axis, and uses as a second maximum wavelength a wavelength corresponding to a sum of the bandgap energy and the thermal energy of the semiconductor at the highest temperature to set one of the two points on the second spectrum as the second maximum wavelength.

17. The semiconductor processing apparatus according to claim 13,
wherein the controller uses as a local maximum wavelength a wavelength corresponding to the bandgap energy of the semiconductor at the highest temperature, calculates as a reference area in the bandedge determination processing a value obtained by multiplying a coefficient K (0<K<1) by integral values from the local minimum wavelength to the local maximum wavelength on the second spectrum, and sets as the bandedge wavelength such a wavelength that the integrated value from the local minimum wavelength becomes the reference area.

18. The semiconductor processing apparatus according to any one of claims 13 to 17,
wherein the controller further performs a smoothing processing due to a moving average on the first spectrum before performing the standardization processing.
